(19) United States
(12) Patent Application Publication
(10) Pub. No.: US 2023/0344409 A1
(43) Pub. Date: Oct. 26, 2023

(54) ACOUSTIC WAVE DEVICE

(71) Applicant: Murata Manufacturing Co., Ltd., Nagaokakyo-shi (JP)

(72) Inventor: Kazunori INOUE, Nagaokakyo-shi (JP)

(21) Appl. No.: 18/210,722

(22) Filed: Jun. 16, 2023

Related U.S. Application Data
(63) Continuation of application No. PCT/JP2021/046995, filed on Dec. 20, 2021.
(60) Provisional application No. 63/129,032, filed on Dec. 22, 2020.

(51) Int. Cl. H03H 9/13; H03H 9/17; H03H 9/02

(52) U.S. Cl. CPC H03H 9/13; H03H 9/173; H03H 9/02031

(57) ABSTRACT

An acoustic wave device includes a support including a support substrate, a piezoelectric layer, an IDT electrode including first and second electrode fingers on the piezoelectric layer, and two wiring electrodes each including two busbars connected to the first and second electrode fingers. A cavity open on a side of the piezoelectric layer is provided in the support. An intersection region is where adjacent first and second electrode fingers overlap each other when viewed in a direction orthogonal to an extending direction of the first and second electrode fingers. The cavity includes the intersection region in plan view. First and second through holes that directly or indirectly reach the cavity are provided in the piezoelectric layer. The first and second through holes face each other with the intersection region being interposed therebetween, and, in plan view, total areas of the first and second through holes differ.

### CROSS REFERENCE TO RELATED APPLICATIONS

This application claims the benefit of priority to Provisional Application No. 63/129,032 filed on Dec. 22, 2020 and is a Continuation Application of PCT Application No. PCT/JP2021/046995 filed on Dec. 20, 2021. The entire contents of each application are hereby incorporated herein by reference.

### BACKGROUND OF THE INVENTION

### 1. Field of the Invention

The present invention relates to an acoustic wave device.

### 2. Description of the Related Art

Hitherto, an acoustic wave device has been widely used in, for example, a filter of a cellular phone. Japanese Unexamined Patent Application Publication No. 2017-224890 discloses an example of an acoustic wave device. In the acoustic wave device, a recessed portion is provided above a support member. A piezoelectric thin film is provided on the support member so as to cover the recessed portion. An IDT (interdigital transducer) electrode is provided on a portion of the piezoelectric thin film, the portion covering the recessed portion.

International Publication No. 2011/052551 discloses an example of an FBAR (film bulk acoustic resonator) as an acoustic wave device. In the acoustic wave device, an upper electrode is provided on one of main surfaces of a piezoelectric thin film. A lower electrode is provided on the other main surface of the piezoelectric thin film. The upper electrode and the lower electrode face each other with the piezoelectric thin film being interposed therebetween.

### SUMMARY OF THE INVENTION

In the acoustic wave device described in International Publication No. 2011/052551, when an alternating-current electric field is applied to a region where the upper electrode and the lower electrode face each other, an acoustic wave is excited. At this time, heat is produced in the aforementioned region. However, in the FBAR, plate-shaped electrodes are provided on the two main surfaces of the piezoelectric thin film. Therefore, a sufficient heat-dissipating path is formed in the two main surfaces of the piezoelectric thin film.

In the acoustic wave device described in Japanese Unexamined Patent Application Publication No. 2017-224890, a sufficient heat-dissipating path such as the heat-dissipating path in the FBAR is not formed in the two main surfaces of the piezoelectric thin film. Therefore, heat that is produced when an acoustic wave is excited propagates toward a recessed portion side of the support member. However, in the acoustic wave device described in Japanese Unexamined Patent Application Publication No. 2017-224890, it is difficult to sufficiently increase heat dissipation from the inside of the recessed portion.

Preferred embodiments of the present invention provide acoustic wave devices each capable of increasing heat dissipation from a cavity portion at a support.

An acoustic wave device according to a preferred embodiment of the present invention includes a support including a support substrate, a piezoelectric layer on the support, a plurality of electrode fingers on the piezoelectric layer, and two wiring electrodes to which the plurality of electrode fingers are connected at one end, wherein the two wiring electrodes each include two busbars, the plurality of electrode fingers are connected at the one end to the two busbars, and an IDT electrode is defined by the two busbars and the plurality of electrode fingers, a cavity open on a side of the piezoelectric layer is in the support, a region where adjacent ones of the electrode fingers overlap each other when viewed in a direction orthogonal to a direction in which the plurality of electrode fingers extend is an intersection region of the IDT electrode, and the cavity portion includes the intersection region in plan view, a first through hole and a second through hole that directly or indirectly reach the cavity portion are in the piezoelectric layer, and the first through hole and the second through hole face each other with the intersection region being interposed therebetween, and in plan view, a total area of the first through hole and a total area of the second through hole differ.

According to the acoustic wave devices according to preferred embodiments of the present invention, it is possible to increase heat dissipation from the cavity portion at the support.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a schematic elevational cross-sectional view of an acoustic wave device according to a first preferred embodiment of the present invention.

FIG. 2 is a schematic plan view of the acoustic wave device according to the first preferred embodiment of the present invention.

FIG. 3 is a schematic elevational cross-sectional view for describing a flow of a gas inside and outside of a cavity portion in the first preferred embodiment of the present invention.

FIG. 4 is a schematic plan view of an acoustic wave device according to a first modification of the first preferred embodiment of the present invention.

FIG. 5 is a schematic plan view of an acoustic wave device according to a second modification of the first preferred embodiment of the present invention.

FIG. 6 is a schematic elevational cross-sectional view of an acoustic wave device according to a third modification of the first preferred embodiment of the present invention.

FIG. 7 is a schematic plan view of an acoustic wave device according to a second preferred embodiment of the present invention.

FIG. 8 is a schematic plan view of an acoustic wave device according to a modification of the second preferred embodiment of the present invention.

FIG. 9 is a schematic plan view of an acoustic wave device according to a third preferred embodiment of the present invention.

FIG. 10 is a schematic plan view of an acoustic wave device according to a modification of the third preferred embodiment of the present invention.

FIG. 11 is a schematic plan view of an acoustic wave device according to a fourth preferred embodiment of the present invention.

FIG. 12 is a schematic plan view of an acoustic wave device according to a fifth preferred embodiment of the present invention.

FIG. 13A is a schematic perspective view showing the exterior of a filter device using bulk waves in a thickness shear mode, and FIG. 13B is a plan view showing an electrode structure at a piezoelectric layer.

FIG. 14 is a cross-sectional view of a portion along line A-A in FIG. 13A.

FIG. 15A is a schematic elevational cross-sectional view for describing lamb waves that propagate in a piezoelectric film of an acoustic wave device, and FIG. 15B is a schematic elevational cross-sectional view for describing bulk waves in a thickness shear mode that propagate in the piezoelectric film in a filter device.

FIG. 16 shows an amplitude direction of bulk waves in a thickness shear mode.

FIG. 17 is a graph showing resonance characteristics of a filter device using bulk waves in a thickness shear mode.

FIG. 18 is a graph showing a relationship between d/p and a fractional band as a resonator, where a center-to-center distance between adjacent electrodes is p and the thickness of a piezoelectric layer is d.

FIG. 19 is a plan view of an acoustic wave device using bulk waves in a thickness shear mode.

FIG. 20 is a graph showing resonance characteristics of an acoustic wave device of a reference example in which a spurious appears.

FIG. 21 is a graph showing a relationship between a fractional band and the phase rotation amount of an impedance of a spurious normalized by 180 degrees as the size of the spurious.

FIG. 22 is a graph showing a relationship between d/2p and a metallization ratio MR.

FIG. 23 is a graph showing a map of a fractional band with respect to Euler angles (0°, θ, ψ) of LiNbO₃ when d/p is set as close as possible to zero.

FIG. 24 is a partial cutaway perspective view for describing an acoustic wave device using lamb waves.

### DETAILED DESCRIPTION OF THE PREFERRED EMBODIMENTS

While referring to the drawings, specific preferred embodiments of the present invention will be described below to clarify the present invention.

Note that each preferred embodiment described in the present description is an exemplification, and it will be pointed out that structures of different preferred embodiments can be partly replaced or combined.

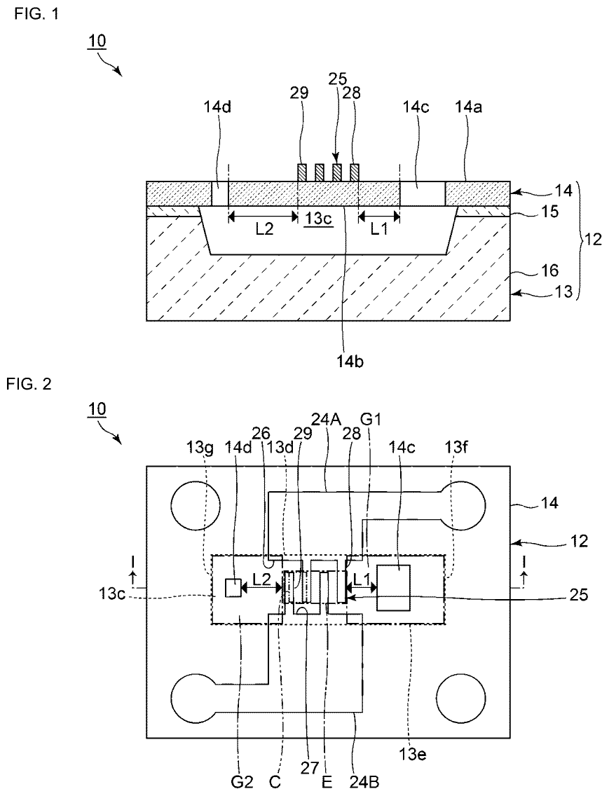

FIG. 1 is a schematic elevational cross-sectional view of an acoustic wave device according to a first preferred embodiment of the present invention. FIG. 2 is a schematic plan view of the acoustic wave device according to the first preferred embodiment. Note that FIG. 1 is a schematic cross-sectional view along line I-I in FIG. 2.

As shown in FIG. 1, an acoustic wave device 10 includes a piezoelectric substrate 12 and an IDT electrode 25. The piezoelectric substrate 12 includes a support member 13 and a piezoelectric layer 14. In the present preferred embodiment, the support member 13 includes a support substrate 16 and an insulating layer 15 as a joining layer. The insulating layer 15 is provided on the support substrate 16. The piezoelectric layer 14 is provided on the insulating layer 15. However, the support member 13 may be defined by only the support substrate 16.

A cavity portion 13c is provided in the support member 13. The cavity portion 13c opens on a side of the piezoelectric layer 14. More specifically, a recessed portion is provided in the support substrate 16. A through hole is provided in the insulating layer 15 so as to be connected to the recessed portion. The insulating layer 15 has a frame shape. The piezoelectric layer 14 is provided on the insulating layer 15 so as to close the through hole. Therefore, the cavity portion 13c of the support member 13 is formed. In the present preferred embodiment, the cavity portion 13c is formed in both the insulating layer 15 and the support substrate 16. Note that the cavity portion 13c may be formed in only the insulating layer 15. Alternatively, the cavity portion 13c may be formed in only the support substrate 16.

As a material of the insulating layer 15, an appropriate dielectric, such as silicon oxide or tantalum pentoxide, can be used.

The piezoelectric layer 14 includes a first main surface 14a and a second main surface 14b. The first main surface 14a and the second main surface 14b face each other. Of the first main surface 14a and the second main surface 14b, the second main surface 14b is the main surface on a side of the support member 13. The piezoelectric layer 14 is made of, for example, lithium niobate, such as LiNbO₃, or lithium tantalate, such as LiTaO₃. In the present description, “a certain member is made of a certain material” includes a case in which a very small amount of impurities that does not cause deterioration in the electrical characteristics of the acoustic wave device is contained.

The IDT electrode 25 is provided on the first main surface 14a of the piezoelectric layer 14. As shown in FIG. 2, the IDT electrode 25 includes a first busbar 26 and a second busbar 27, which are a pair of busbars, a plurality of first electrode fingers 28, and a plurality of second electrode fingers 29. Each first electrode finger 28 is a first electrode. The plurality of first electrode fingers 28 are periodically disposed. One end of each of the plurality of first electrode fingers 28 is connected to the first busbar 26. Each second electrode finger 29 is a second electrode. The plurality of second electrode fingers 29 are periodically disposed. One end of each of the plurality of second electrode fingers 29 is connected to the second busbar 27. The plurality of first electrode fingers 28 and the plurality of second electrode fingers 29 interdigitate with respect to each other. The IDT electrode 25 may be formed from a multilayer metal film, or may be formed from a single-layer metal film. In the description below, the first electrode fingers 28 and the second electrode fingers 29 may simply be referred to as electrode fingers.

When a direction in which electrode fingers that are adjacent to each other is an electrode-finger facing direction and a direction in which the plurality of electrode fingers extend is an electrode-finger extending direction, in the present preferred embodiment, the electrode-finger facing direction is orthogonal to the electrode-finger extending direction. A region in which the electrode fingers that are adjacent to each other overlap each other when viewed from the electrode-finger facing direction is an intersection region E. The intersection region E is a region including a portion of the IDT electrode 25 from an electrode finger at one end in the electrode-finger facing direction to an electrode finger on the other end in the electrode-finger facing direction. More specifically, the intersection region E includes a portion from an outer edge portion in the electrode-finger facing direction of the electrode finger at the one end to an outer edge portion in the electrode-finger facing direction of the electrode finger at the other end. Note that, in plan view, the cavity portion 13c of the support member 13 is disposed so as to include the intersection region E. In the present description, “in plan view” refers to a view from a direction corresponding to an upper direction in FIG. 1.

Further, the acoustic wave device 10 includes a plurality of excitation regions C. Acoustic waves are excited in the plurality of excitation regions C by applying an alternating-current voltage to the IDT electrode 25. In the present preferred embodiment, the acoustic wave device 10 is configured to be capable of using, for example, bulk waves in a thickness shear mode, such as a thickness shear primary mode. Similarly to the intersection region E, each excitation region C is a region in which the electrode fingers that are adjacent to each other overlap each other when viewed from the electrode-finger facing direction. Note that each excitation region C is a region between a pair of electrode fingers. More specifically, each excitation region C is a region from the center of one of the electrode fingers in the electrode-finger facing direction to the center of the other electrode finger in the electrode-finger facing direction. Therefore, the intersection region E includes the plurality of excitation regions C. However, the acoustic wave device 10 may be configured to be capable of using, for example, plate waves. When the acoustic wave device 10 uses plate waves, the intersection region E becomes an excitation region.

A first wiring electrode 24A and a second wiring electrode 24B, which are a pair of wiring electrodes, are provided on the first main surface 14a of the piezoelectric layer 14. The first wiring electrode 24A includes the first busbar 26. The first wiring electrode 24A is, at a portion of the first busbar 26, connected to one end of each of the plurality of first electrode fingers 28. Similarly, the second wiring electrode 24B includes the second busbar 27. The second wiring electrode 24B is, at a portion of the second busbar 27, connected to one end of each of the plurality of second electrode fingers 29.

A first through hole 14c and a second through hole 14d reaching the cavity portion 13c are provided in the piezoelectric layer 14. The first through hole 14c and the second through hole 14d face each other with the intersection region E being interposed therebetween.

One of the unique features of the present preferred embodiment is that the first through hole 14c and the second through hole 14d face each other with the intersection region E being interposed therebetween and that, in plan view, the total area of the first through 14c and the total area of the second through hole 14d differ from each other. This makes it possible to increase heat dissipation from the cavity portion 13c in the support member 13. The details thereof are described below. Note that, in the description below, the area of a through hole in plan view may be simply referred as the area of a through hole.

In the present preferred embodiment, specifically, one first through hole 14c and one second through hole 14d are provided, and the area of the first through hole 14c is larger than the area of the second through hole 14d. In the present description, “the areas of the through holes differ from each other” means that the area of one of the through holes is greater than or equal to about 115% of the area of the other through hole, or is less than or equal to about 85% of the area of the other through hole, for example.

The area of each through hole is calculated by image processing software after obtaining an image of each through hole by, for example, an optical observation apparatus, a length measuring SEM, or an X-ray CT. Examples of the optical observation apparatus can include microscopes, such as laser microscopes and infrared microscopes, and digital microscopes. When the shape of each through hole in plan view is close to a circular shape, by using image processing software, the shape may be approximated to a circle and the diameter may be measured to calculate the area. However, it is preferable to calculate the area after performing image recognition of the accurate shape of each through hole by using image processing software. The details of the aforementioned effect of making it possible to increase heat dissipation are described below.

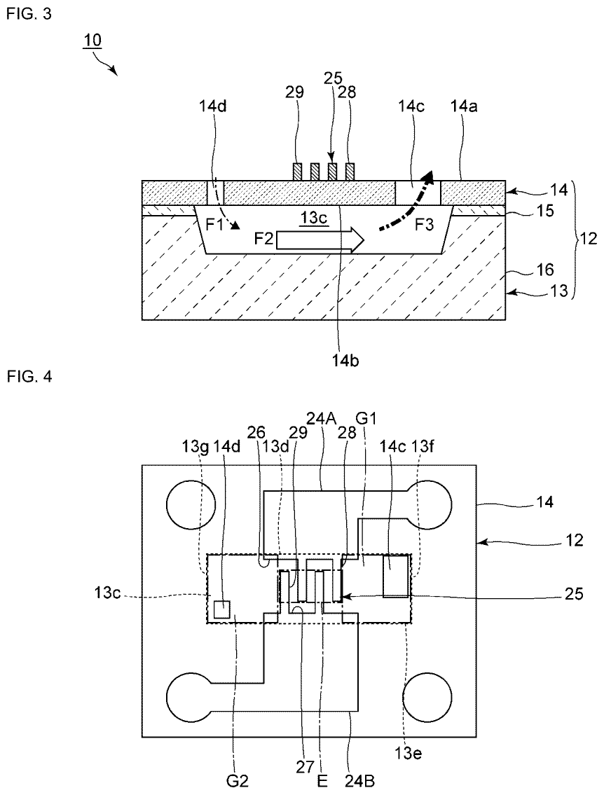

FIG. 3 is a schematic elevational cross-sectional view for describing a flow of a gas inside and outside of the cavity portion in the first preferred embodiment.

When an acoustic wave is excited, heat is produced at a portion where the IDT electrode 25 is provided. When this heat heats a gas inside the cavity portion 13c of the support member 13, the internal pressure inside the cavity portion 13c is increased. At this time, the gas inside the cavity portion 13c is easily discharged to the outside from the first through hole 14c whose area is relatively larger. Therefore, an air current flowing from a region where the second through hole 14d, whose area is relatively smaller is provided, toward a region where the first through hole 14c is provided is produced. In FIG. 3, this air current is denoted by an arrow F1, an arrow F2, and an arrow F3. Therefore, it is possible to increase heat dissipation from the cavity portion 13c in the support member 13.

The total area of one of the first through hole 14c and the second through hole 14d is preferably greater than or equal to about 120% and less than or equal to about 80% of the total area of the other of the first through hole 14c and the second through hole 14d, is more preferably greater than or equal to about 125% and less than or equal to about 75% of the total area of the other of the first through hole 14c and the second through hole 14d, and is even more preferably greater than or equal to about 130% and less than or equal to about 70% of the total area of the other of the first through hole 14c and the second through hole 14d, for example. This makes it possible to further increase heat dissipation.

As shown in FIG. 1, when the distance between an edge portion of the first through hole 14c and the intersection region E is L1 and the distance between an edge portion of the second through hole 14d and the intersection region E is L2, it is preferable that the distance L1 be shorter than the distance L2. Therefore, it is possible to reduce the distance from each excitation region C, which is a heat source, to the first through hole 14c, which is a gas outlet. Consequently, it is possible to effectively increase heat dissipation.

The acoustic wave device 10 includes a first region G1 and a second region G2. The first through hole 14c is provided in the first region G1. The second through hole 14d is provided in the second region G2. As shown in FIG. 2, the first region G1 and the second region G2 overlap the cavity portion 13c of the support member 13 in plan view. More specifically, the first region G1 and the second region G2 face each other with the intersection region E being interposed therebetween. Note that, in plan view, the first region G1 and the second region G2 may each include a portion that does not overlap the cavity portion 13c. It is sufficient for the first region G1 and the second region G2 to face each other with the intersection region E being interposed therebetween. However, in plan view, the first region G1 and the second region G2 of the present preferred embodiment do not include a region that does not overlap the cavity portion 13c.

Note that the cavity portion 13c includes a first edge portion 13d, a second edge portion 13e, a third edge portion 13f, and a fourth edge portion 13g. The first edge portion 13d and the second edge portion 13e face each other in the electrode-finger extending direction. The third edge portion 13f and the fourth edge portion 13g face each other in the electrode-finger facing direction. The first edge portion 13d and the second edge portion 13e are connected to each of the third edge portion 13f and the fourth edge portion 13g. In the present preferred embodiment, the shape of the cavity portion 13c in plan view is a rectangular or substantially rectangular shape. Therefore, the first edge portion 13d, the second edge portion 13e, the third edge portion 13f, and the fourth edge portion 13g are all linear. However, at least one of the first edge portion 13d, the second edge portion 13e, the third edge portion 13f, and the fourth edge portion 13g may be curved.

In the present preferred embodiment, one end portion of the first region G1 and one end portion of the second region G2 in the electrode-finger extending direction overlap a portion of the first edge portion 13d of the support member 13 in plan view. The other end portion of the first region G1 and the other end portion of the second region G2 in this direction overlap a portion of the second edge portion 13e in plan view.

One end portion of the first region G1 in a direction parallel to the electrode-finger facing direction overlaps the third edge portion 13f of the support member 13 in plan view. The other end portion of the first region G1 in this direction includes an end portion of the intersection region E in the electrode-finger facing direction. One end portion of the second region G2 in the direction parallel to the electrode-finger facing direction overlaps the fourth edge portion 13g of the support member 13 in plan view. The other end portion of the second region G2 in this direction includes an end portion of the intersection region E in the electrode-finger facing direction. Note that an end portion of the intersection region E, which is a portion of an end portion of the first region G1, and an end portion of the intersection region E, which is a portion of an end portion of the second region G2, face each other.

As shown in FIG. 2, in the present preferred embodiment, two end portions of the intersection region E in the electrode-finger facing direction are positioned on a straight line connecting the center of the first through hole 14c and the center of the second through hole 14d. More specifically, the first through hole 14c and the second through hole 14d are disposed such that a straight line extending in the electrode-finger facing direction and passing through the center of the intersection region E in the electrode-finger extending direction passes through both of the first through hole 14c and the second through hole 14d. However, the position of the first through hole 14c and the position of the second through hole 14d are not limited to the aforementioned positions. It is sufficient for the first through hole 14c to be provided in the first region G1 and the second through hole 14d to be provided in the second region G2.

For example, in a first modification of the first preferred embodiment shown in FIG. 4, in plan view, the first through hole 14c and the second through hole 14d are provided so as to overlap one of diagonal lines of the cavity portion 13c of the support member 13. Even in the present modification, it is possible to increase heat dissipation from the cavity portion 13c.

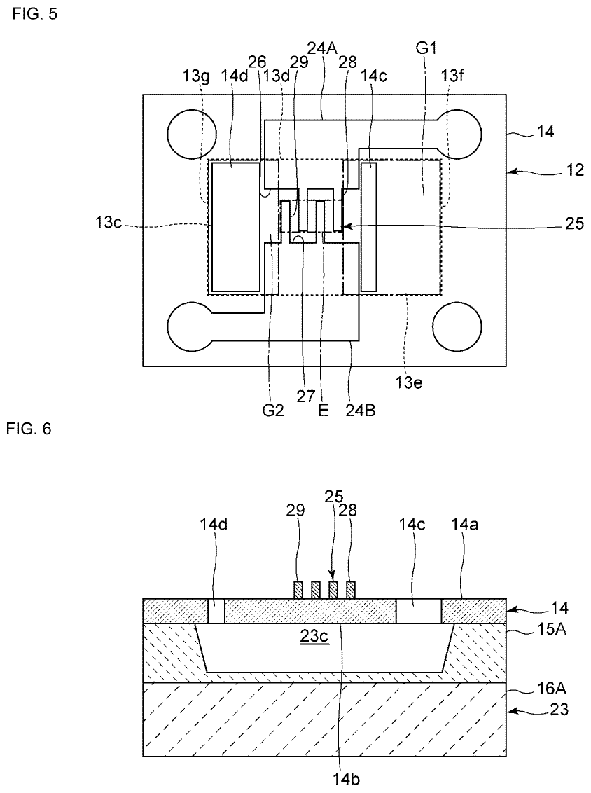

In a second modification of the first preferred embodiment shown in FIG. 5, when viewed from a direction parallel to the electrode-finger facing direction, the first through hole 14c overlaps the entire intersection region E and overlaps both of the first busbar 26 and the second busbar 27. Similarly, when viewed from the direction parallel to the electrode-finger facing direction, the second through hole 14d overlaps the entire intersection region E and overlaps both of the first busbar 26 and the second busbar 27. Note that, in the present modification, the area of the second through hole 14d is larger than the area of the first through hole 14c. Even in the present modification, it is possible to increase heat dissipation from the cavity portion 13c.

As described above, the cavity portion 13c of the support member 13 is not limited to the case in which the cavity portion 13c is provided in both of the support substrate 16 and the insulating layer 15. For example, in a third modification of the first preferred embodiment shown in FIG. 6, a cavity portion 23c of the support member 23 may be formed only in an insulating layer 15A. More specifically, a recessed portion is provided in the insulating layer 15A. On the other hand, a recessed portion is not provided in a support substrate 16A. Even in the present modification, it is possible to increase heat dissipation from the cavity portion 23c.

In the first preferred embodiment and each modification, in plan view, the cavity portion 13c overlaps both of the first busbar 26 and the second busbar 27. A diagonal line of the cavity portion 13c in plan view passes through two end portions of the intersection region E in the electrode-finger facing direction. Note that the size of the cavity portion 13c is not limited to the aforementioned size.

In the first preferred embodiment, the first region G1 and the second region G2 face each other in a direction parallel to the electrode-finger facing direction with the intersection region E being interposed therebetween. However, the position of the first region G1 and the position of the second region G2 are not limited to the aforementioned positions. The first region G1 and the second region G2 may face each other in a direction parallel to the electrode-finger extending direction.

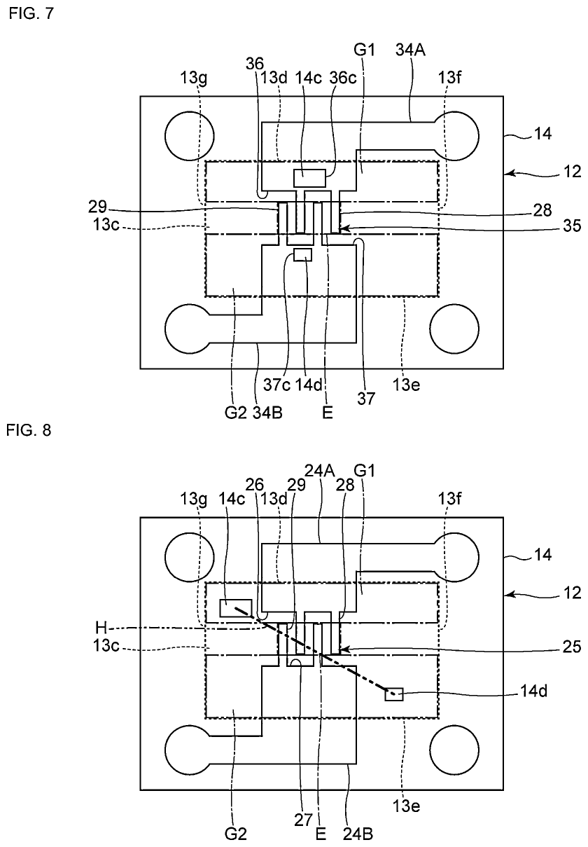

FIG. 7 is a schematic plan view of an acoustic wave device according to a second preferred embodiment of the present invention.

The present preferred embodiment differs from the first preferred embodiment in the position of a first region G1 and the position of a second region G2, and in the position of a first through hole 14c and the position of a second through hole 14d. The present preferred embodiment also differs from the first preferred embodiment in that a diagonal line of a cavity portion 13c in plan view passes through at least one of two end portions of an intersection region E in the electrode-finger extending direction. In terms of points other than the aforementioned points, the structure of the acoustic wave device of the present preferred embodiment is the same as the structure of the acoustic wave device 10 of the first preferred embodiment.

As shown in FIG. 7, the first region G1 and the second region G2 face each other in a direction parallel to the electrode-finger extending direction. More specifically, the first region G1 is positioned on a first busbar 36 side of an IDT electrode 35. The second region G2 is positioned on a side of a second busbar 37.

One end portion of the first region G1 in a direction parallel to the electrode-finger extending direction overlaps a first edge portion 13d of a support member 13 in plan view. The other end portion of the first region G1 in this direction includes an end portion of the intersection region E in the electrode-finger extending direction. One end portion of the second region G2 in a direction parallel to the electrode-finger extending direction overlaps a second edge portion 13e in plan view. The other end portion of the second region G2 in this direction includes an end portion of the intersection region E in the electrode-finger extending direction. Note that an end portion of the intersection region E, which is a portion of an end portion of the first region G1, and an end portion of the intersection region E, which is a portion of an end portion of the second region G2, face each other.

One end portion of the first region G1 and one end portion of the second region G2 in a direction parallel to the electrode-finger facing direction overlap a portion of a third edge portion 13f of the support member 13 in plan view. The other end portion of the first region G1 and the other end portion of the second region G2 in this direction overlap a portion of a fourth edge portion 13g in plan view.

In plan view, the first through hole 14c overlaps the first busbar 36 of an IDT electrode 35. A through hole 36c integrated with the first through hole 14c is provided in the first busbar 36. On the other hand, in plan view, the second through hole 14d overlaps the second busbar 37. A through hole 37c integrated with the second through hole 14d is provided in the second busbar 37. Therefore, a portion of a piezoelectric layer 14 that is in the vicinity of the first through hole 14c and the second through hole 14d is protected by the first busbar 36 and the second busbar 37. Consequently, it is possible to reduce or prevent cracks from occurring in the piezoelectric layer 14.

Further, even in the present preferred embodiment, similarly to the first preferred embodiment, the first through hole 14c and the second through hole 14d face each other with the intersection region E being interposed therebetween, and the area of the first through hole 14c is larger than the area of the second through hole 14d. Therefore, it is possible to produce an air current inside the cavity portion 13c of the support member 13 and to increase heat dissipation from the cavity portion 13c.

Note that the first through hole 14c may be provided in a portion of a first wiring electrode 34A other than a portion where the first busbar 36 is provided. A through hole integrated with the first through hole 14c may be provided in this portion. Similarly, the second through hole 14d may be provided in a portion of a second wiring electrode 34B other than a portion where the second busbar 37 is provided. A through hole integrated with the second through hole 14d may be provided in this portion.

In the present preferred embodiment, two end portions of the intersection region E in the electrode-finger extending direction are positioned on a straight line connecting the first through hole 14c and the second through hole 14d. However, it is not limited thereto. For example, in a modification of the second preferred embodiment shown in FIG. 8, one end portion of the intersection region E in the electrode-finger facing direction and one end portion of the intersection region E in the electrode-finger extending direction are positioned on a straight line H connecting the first through hole 14c and the second through hole 14d. Note that, in the present modification, in plan view, the first through hole 14c does not overlap the first busbar 26, and the second through hole 14d does not overlap the second busbar 27. Even in the present modification, similarly to the second preferred embodiment, it is possible to increase heat dissipation.

In the first preferred embodiment and the second preferred embodiment, the first through hole 14c and the second through hole 14d directly reach the cavity portion 13c. Note that the first through hole 14c and the second through hole 14d may indirectly reach the cavity portion 13c. This example is described by a third preferred embodiment.

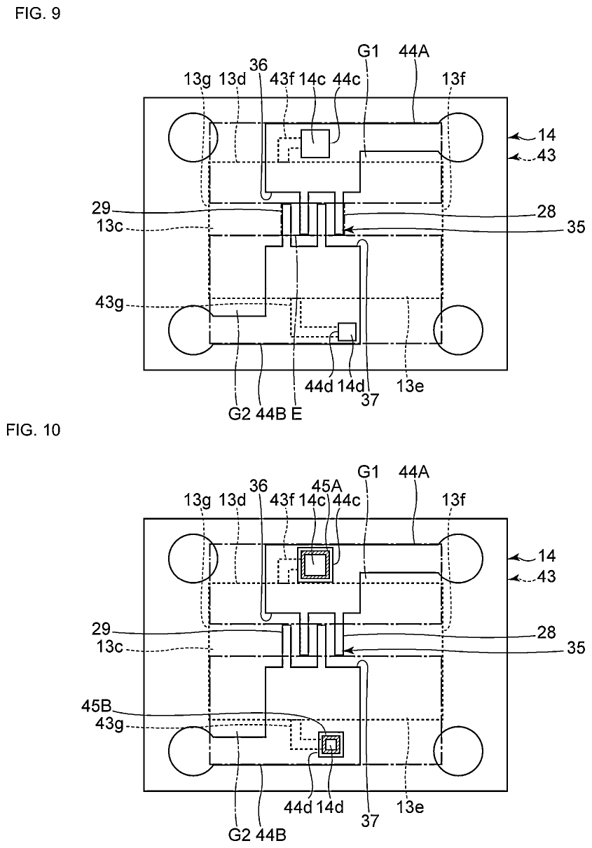

FIG. 9 is a schematic plan view of an acoustic wave device according to a third preferred embodiment.

The present preferred embodiment differs from the second preferred embodiment in that a first through hole 14c and a second through hole 14d of a piezoelectric layer 14 indirectly reach a cavity portion 13c, and in that a first region G1 and a second region G2 each include a portion that does not overlap the cavity portion 13c in plan view. The present preferred embodiment also differs from the second preferred embodiment in that a through hole 44c of a first wiring electrode 44A and a through hole 44d of a second wiring electrode 44B are provided at portions other than portions where the busbars are provided. In terms of points other than the aforementioned points, the structure of the acoustic wave device of the present preferred embodiment is the same as the structure of the acoustic wave device of the second preferred embodiment.

The first through hole 14c is provided at a position in the first region G1 that does not overlap the cavity portion 13c in plan view. Similarly to the second preferred embodiment, the through hole 44c integrated with the first through hole 14c is provided in the first wiring electrode 44A. Therefore, the through hole 44c overlaps the first through hole 14c in plan view. However, the through hole 44c is provided in a portion of the first wiring electrode 44A other than a portion where the first busbar 36 is provided. Similarly, the second through hole 14d is provided at a position in the second region G2 that does not overlap the cavity portion 13c in plan view. The through hole 44d integrated with the second through hole 14d is provided in the second wiring electrode 44B. The through hole 44d is provided in a portion of the second wiring electrode 44B other than a portion where the second busbar 37 is provided.

On the other hand, a path 43f and a path 43g are provided in a support member 43. The path 43f and the path 43g are hollow paths. The path 43f connects the first through hole 14c and the cavity portion 13c to each other. In plan view, the path 43f overlaps the first wiring electrode 44A. The path 43g connects the second through hole 14d and the cavity portion 13c to each other. In plan view, the path 43g overlaps the second wiring electrode 44B.

Note that, similarly to the first preferred embodiment and the second preferred embodiment, the support member 43 includes the insulating layer 15 and the support substrate 16 shown in FIG. 1. The paths 43f and 43g shown in FIG. 9 may be provided in only the insulating layer 15 or may be provided in both of the insulating layer 15 and the support substrate 16.

Even in the present preferred embodiment, similarly to the second preferred embodiment, the first through hole 14c and the second through hole 14d face each other with an intersection region E being interposed therebetween, and the area of the first through hole 14c is larger than the area of the second through hole 14d. The first through hole 14c and the second through hole 14d each indirectly reach the cavity portion 13c through a corresponding one of the path 43f and the path 43g. Even in this case, it is possible to produce an air current inside the cavity portion 13c of the support member 43 and to increase heat dissipation from the cavity portion 13c.

In the second preferred embodiment and the present preferred embodiment, an inside wall defining the through hole of the first wiring electrode is flush with an inside wall defining the first through hole 14c of the piezoelectric layer 14. Note that the inside wall defining the through hole of the first wiring electrode and the inside wall defining the first through hole 14c of the piezoelectric layer 14 need not be flush with each other. For example, in a modification of the third preferred embodiment shown in FIG. 10, in plan view, an outer peripheral edge defining the first through hole 14c and an outer peripheral edge defining the through hole 44c of the first wiring electrode 44A do not overlap each other. More specifically, in plan view, the outer peripheral edge defining the through hole 44c is positioned on an outer side of the outer peripheral edge defining the first through hole 14c. Similarly, in plan view, an outer peripheral edge defining the through hole 44d of the second wiring electrode 44B is positioned on an outer side of an outer peripheral edge defining the second through hole 14d.

In this case, as indicated by hatching in FIG. 10, a metal film 45A is preferably provided at the inside wall defining the first through hole 14c. Similarly, a metal film 45B is preferably provided at the inside wall defining the second through hole 14d. Therefore, portions of the piezoelectric layer 14 where the first through hole 14c and the second through hole 14d are provided are reinforced. In addition, the metal film 45A is not connected to the first wiring electrode 44A. The metal film 45B is not connected to the second wiring electrode 44B. Consequently, since the electrical characteristics of the acoustic wave device are not affected, it is possible to make it unlikely for the piezoelectric layer 14 to be damaged.

In the present preferred embodiment, an example in which the first region G1 and the second region G2 face each other in the electrode-finger extending direction and in which the first through hole 14c and the second through hole 14d indirectly reach the cavity portion 13c has been given. However, similarly to the first preferred embodiment, the first region G1 and the second region G2 may face each other in the electrode-finger facing direction, and the first through hole 14c and the second through hole 14d may indirectly reach the cavity portion 13c. In this case, in plan view, the path 43f and the path 43g need not overlap the first busbar 26 or the second busbar 27.

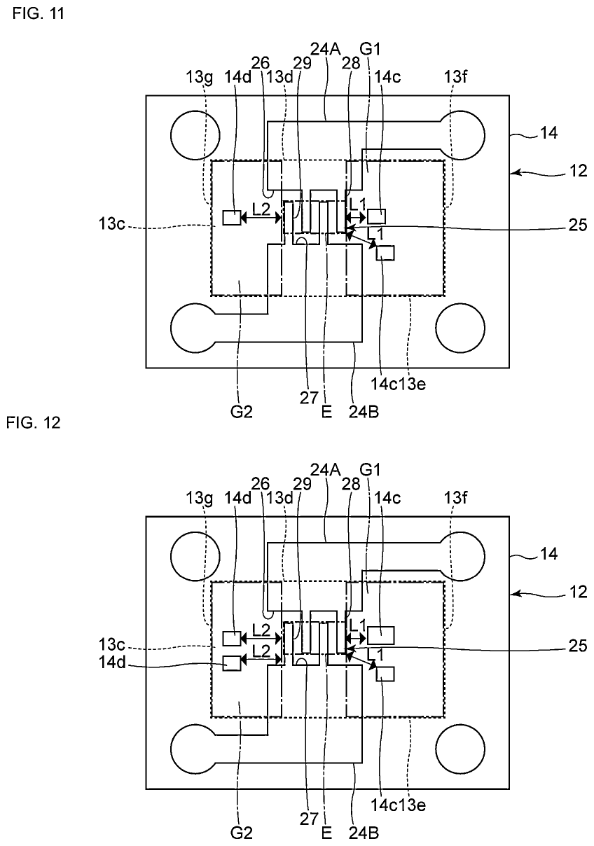

FIG. 11 is a schematic plan view of an acoustic wave device according to a fourth preferred embodiment.

The present preferred embodiment differs from the first preferred embodiment in that a plurality of first through holes 14c are provided in a first region G1 and that the area of each first through hole 14c and the area of a second through hole 14d are the same. The present preferred embodiment also differs from the first preferred embodiment in that a diagonal line of a cavity portion 13c in plan view passes through at least one of two end portions of an intersection region E in the electrode-finger extending direction. In terms of points other than the aforementioned points, the structure of the acoustic wave device of the present preferred embodiment is the same as the structure of the acoustic wave device 10 of the first preferred embodiment.

As shown in FIG. 11, the number of first through holes 14c and the number of second through holes 14d differ from each other. More specifically, two first through holes 14c are provided, and one second through hole 14d is provided. In addition, as described above, the area of each first through hole 14c and the area of the second through hole 14d are the same. Therefore, the total area of the first through holes 14c is larger than the total area of the second through hole 14d. That is, the first region G1 is a region in which the total area of the through holes in a piezoelectric layer 14 is relatively larger. A second region G2 is a region in which the total area of the through hole is relatively smaller. Note that the number of first through holes 14c and the number of second through holes 14d are not limited to the aforementioned numbers.

Even in the present preferred embodiment, each first through hole 14c and the second through hole 14d face each other with the intersection region E being interposed therebetween, and the total area of the first through holes 14c is larger than the total area of the second through hole 14d. Therefore, similarly to the first preferred embodiment, it is possible to produce an air current inside the cavity portion 13c of a support member 13 and to increase heat dissipation from the cavity portion 13c.

Of distances L1 between the plurality of the first through holes 14c and the intersection region E, all of the distances L1 are shorter than a distance L2 between the second through hole 14d and the intersection region E. Therefore, it is possible to reduce the distance from an excitation region C, which is a heat source, up to each first through hole 14c, which is an air outlet. Consequently, it is possible to effectively increase heat dissipation.

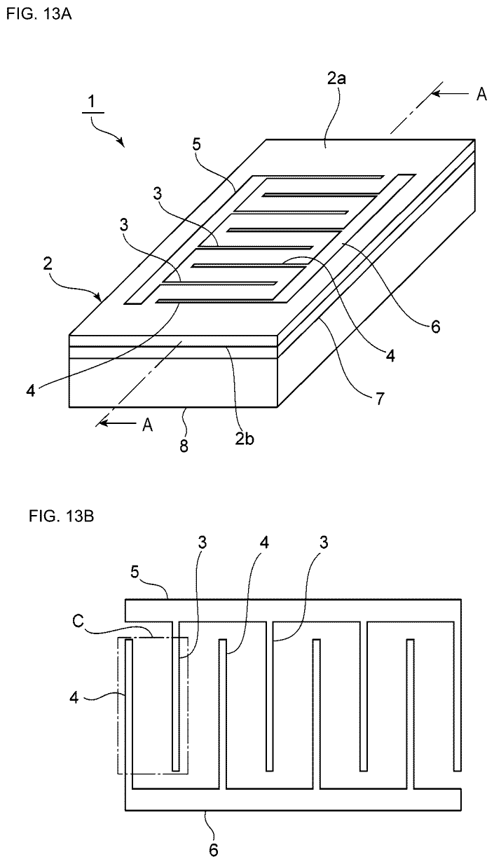

FIG. 12 is a schematic plan view of an acoustic wave device according to a fifth preferred embodiment.

The present preferred embodiment differs from the fourth preferred embodiment in that a plurality of second through holes 14d are provided and in that a plurality of first through holes 14c having different areas are included. In terms of points other than the aforementioned points, the structure of the acoustic wave device of the present preferred embodiment is the same as the structure of the acoustic wave device of the fourth preferred embodiment.

As shown in FIG. 12, the number of first through holes 14c and the number of second through holes 14d are the same. More specifically, two first through holes 14c are provided and two second through holes 14d are provided. Although the area of one of the first through holes 14c is the same as the area of each second through hole 14d, the area of the other first through hole 14c is larger than the area of each second through hole 14d. Therefore, the total area of the first through holes 14c is larger than the total area of the second through holes 14d.

Even in the present preferred embodiment, similarly to the fourth preferred embodiment, the plurality of first through holes 14c and the plurality of second through holes 14d face each other with an intersection region E being interposed therebetween, and the total area of the first through holes 14c is larger than the total area of the second through holes 14d. Therefore, it is possible to produce an air current inside a cavity portion 13c of a support member 13 and to increase heat dissipation from the cavity portion 13c.

Of distances L1 between the plurality of first through holes 14c and the intersection region E, all of the distances L1 are preferably shorter than a shortest distance L2 of distances between the plurality of second through holes 14d and the intersection region E. Therefore, it is possible to reduce the distance from each excitation region C, which is a heat source, to each first through hole 14c, which is a gas outlet. Consequently, it is possible to effectively increase heat dissipation.

The distance L1 between the intersection region E and, of the plurality of first through holes 14c, the through hole having the largest area is preferably the shortest distance of the distances L1 between the plurality of first through holes 14c and the intersection region E. Consequently, it is possible to further increase heat dissipation.

In the present preferred embodiment, each second through hole 14d has the same area. However, the plurality of second through holes 14d may have different areas.

In the first preferred embodiment to the fifth preferred embodiment and each modification, in each first through hole 14c, the opening area at the first main surface 14a of the piezoelectric layer 14 is the same as the opening area at the second main surface 14b. Similarly, in each second through hole 14d, the opening areas at both main surfaces of the piezoelectric layer 14 are the same. Note that, in each of the first through holes 14c and the second through holes 14d, the opening areas at both main surfaces of the piezoelectric layer 14 may differ from each other. In this case, the total area of the smaller opening areas of the first through holes 14c and the total area of the smaller opening areas of the second through holes 14d preferably differ from each other.

Each distance L1 between the corresponding first through hole 14c and the intersection region E is preferably a distance between the intersection region E and an edge portion of the first through hole 14c on a side of the second main surface 14b of the piezoelectric layer 14 in plan view. Similarly, each distance L2 between the corresponding second through hole 14d and the intersection region E is preferably a distance between the intersection region E and an edge portion of the second through hole 14d on a side of the second main surface 14b in plan view.

Note that, even if a plurality of first through holes 14c or a plurality of second through holes 14d are provided, the first through holes 14c or the second through holes 14d may each indirectly reach the cavity portion 13c through the path 43f or the path 43g.

Details of an acoustic wave device using bulk waves in a thickness shear mode are described below. Note that a support member below corresponds to the above-described support substrate.

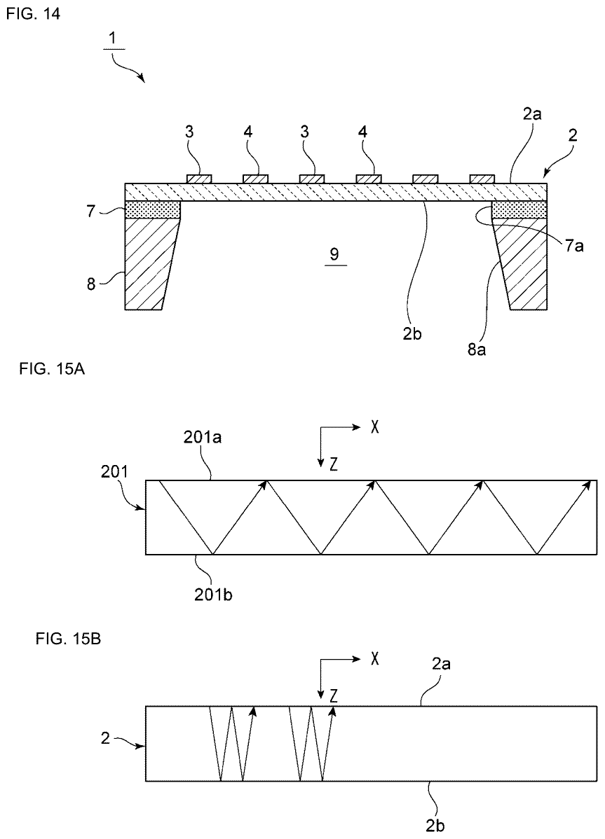

FIG. 13A is a schematic perspective view showing the exterior of an acoustic wave device using bulk waves in a thickness shear mode, FIG. 13B is a plan view showing an electrode structure at a piezoelectric layer, and FIG. 14 is a cross-sectional view of a portion along line A-A in FIG. 13A.

An acoustic wave device 1 includes a piezoelectric layer 2 made of LiNbO₃. The piezoelectric layer 2 may be made of LiTaO₃. Although the cut-angle of LiNbO₃ and LiTaO₃ is Z-cut, the cut-angle may be rotation Y-cut or X-cut. Although the thickness of the piezoelectric layer 2 is not particularly limited, the thickness of the piezoelectric layer 2 is preferably more than or equal to about 40 nm and less than or equal to about 1000 nm and more preferably more than or equal to about 50 nm and less than or equal to about 1000 nm, for example, to excite the thickness shear mode effectively. The piezoelectric layer 2 includes a first main surface 2a and a second main surface 2b that face each other. An electrode 3 and an electrode 4 are provided on the first main surface 2a. Here, the electrode 3 is one example of the “first electrode”, and the electrode 4 is one example of the “second electrode”. In FIGS. 13A and 13B, a plurality of the electrodes 3 are connected to a first busbar 5. A plurality of the electrodes 4 are connected to a second busbar 6. The plurality of electrodes 3 and the plurality of electrodes 4 interdigitate with each other. The electrodes 3 and the electrodes 4 each have a rectangular or substantially rectangular shape and have a length direction. In a direction orthogonal to this length direction, each electrode 3 faces adjacent one or ones of the electrodes 4. The length directions of the electrodes 3 and 4 and a direction orthogonal to the length directions of the electrodes 3 and 4 are each a direction intersecting the thickness direction of the piezoelectric layer 2. Therefore, it can be said that each electrode 3 and the adjacent one or ones of the electrodes 4 face each other in the direction intersecting the thickness direction of the piezoelectric layer 2. The length directions of the electrodes 3 and 4 may be replaced with a direction orthogonal to the length directions of the electrodes 3 and 4 illustrated in FIGS. 13A and 13B. In other words, in FIGS. 13A and 13B, the electrodes 3 and 4 may extend in the direction in which the first busbar 5 and the second busbar 6 extend. In this case, the first busbar 5 and the second busbar 6 extend in the direction in which the electrodes 3 and 4 extend in FIGS. 13A and 13B. Then, a plurality of pairs of a structure in each of which the electrode 3 connected to one potential and the electrode 4 connected to the other potential are adjacent to each other are provided in the direction orthogonal to the length directions of the aforementioned electrodes 3 and 4. Here, “the electrode 3 and the electrode 4 are adjacent to each other” does not refer to a case in which the electrode 3 and the electrode 4 are disposed in direct contact with each other but refers to a case in which the electrode 3 and the electrode 4 are disposed with a gap interposed therebetween. When the electrode 3 and the electrode 4 are adjacent to each other, electrodes, including the other electrodes 3 and 4, connected to a hot electrode and a ground electrode are not disposed between the electrode 3 and the electrode 4. The number of the pairs is not necessarily an integer number and may be, for example, 1.5 or 2.5. A center-to-center distance, that is, a pitch between the electrode 3 and the electrode 4 is preferably within the range from about 1 μm to about 10 μm, for example. The width of each of the electrodes 3 and 4, that is, the dimension thereof in the facing direction of the electrodes 3 and 4 is preferably within the range from about 50 nm to about 1000 nm and more preferably within the range from about 150 nm to about 1000 nm, for example. Note that the center-to-center distance between the electrodes 3 and 4 is a distance that connects the center of the dimension (width dimension) of the electrode 3 in a direction orthogonal to the length direction of the electrode 3 and the center of a dimension (width dimension) of the electrode 4 in a direction orthogonal to the length direction of the electrode 4 to each other.

In the acoustic wave device 1, a Z-cut piezoelectric layer is used, and thus, the directions orthogonal to the length directions of the electrodes 3 and 4 are directions orthogonal to a polarization direction of the piezoelectric layer 2. The above is not applicable to a case where a piezoelectric body of other cut-angles is used as the piezoelectric layer 2.

Here, “orthogonal” does not only refer to orthogonal in the strict sense and may refer to “substantially orthogonal” (an angle formed by the direction orthogonal to the length direction of the electrode 3 or 4 and the polarization direction may be, for example, in the range of about 90°±10°).

A support member 8 is laminated on the side of the second main surface 2b of the piezoelectric layer 2 with an insulating layer 7 interposed therebetween. The insulating layer 7 and the support member 8 each have a frame shape and, as illustrated in FIG. 14, have through holes 7a and 8a, respectively. Consequently, a cavity portion 9 is formed. The cavity portion 9 is provided so that vibration of the excitation regions C of the piezoelectric layer 2 is not obstructed. Accordingly, the support member 8 is laminated on the second main surface 2b with the insulating layer 7 interposed therebetween at a position not overlapping a portion at which at least a pair of the electrodes 3 and 4 is provided. Note that the insulating layer 7 need not be provided. Accordingly, the support member 8 is laminated on the second main surface 2b of the piezoelectric layer 2 directly or indirectly.

The insulating layer 7 is made of silicon oxide. However, an appropriate insulating material, other than silicon oxide, such as silicon oxynitride or alumina is usable. The support member 8 is made of Si. The orientation of Si at a surface on the piezoelectric layer 2 side may be (100) or (110), or may be (111). Desirably, the Si of which the support member 8 is made is highly resistive with a resistivity of more than or equal to about 4 kΩcm, for example. However, the support member 8 can also be made of an appropriate insulating material or an appropriate semiconductor material.

Examples of materials usable as the material of the support member 8 include a piezoelectric body, such as aluminum oxide, lithium tantalate, lithium niobate, or crystal; various types of ceramic materials, such as alumina, magnesia, sapphire, silicon nitride, aluminum nitride, silicon carbide, zirconia, cordierite, mullite, steatite, or forsterite; a dielectric, such as diamond or glass; or a semiconductor, such as gallium nitride.

The plurality of electrodes 3 and 4 and the first and second busbars 5 and 6 are each made of an appropriate metal or an appropriate alloy, such as Al or an AlCu alloy. In the present preferred embodiment, the electrodes 3 and 4, and the first and second busbars 5 and 6 each have a structure in which an Al film is laminated on a Ti film. Note that a close-contact layer other than the Ti film may be used.

An alternating-current voltage is applied between the plurality of electrodes 3 and the plurality of electrodes 4 to perform driving. More specifically, the alternating-current voltage is applied between the first busbar 5 and the second busbar 6. Consequently, it is possible to obtain resonance characteristics by using bulk waves in a thickness shear mode excited in the piezoelectric layer 2. In addition, in the acoustic wave device 1, when the thickness of the piezoelectric layer 2 is d and the center-to-center distance between, among the plurality of pairs of electrodes 3 and 4, electrodes 3 and 4 that are adjacent to each other is p, d/p is less than or equal to about 0.5, for example. Therefore, bulk waves in the thickness shear mode are effectively excited, and satisfactory resonance characteristics can be obtained. More preferably, d/p is less than or equal to about 0.24, for example. In this case, more satisfactory resonance characteristics can be obtained.

In the acoustic wave device 1, due to having the aforementioned configuration, the Q-value is unlikely to decrease, even when the number of pairs of the electrodes 3 and 4 is reduced to downsize the acoustic wave device 1. This is because, propagation loss is small even when the number of the electrode fingers of reflectors on both sides is reduced. The number of the electrode fingers can be reduced due to the use of bulk waves in the thickness shear mode. A difference between lamb waves used in an acoustic wave device and bulk waves in the thickness shear mode will be described with reference to FIGS. 15A and 15B.

FIG. 15A is a schematic elevational cross-sectional view for describing lamb waves that propagate in a piezoelectric film of an acoustic wave device such as that described in Japanese Unexamined Patent Application Publication No. 2012-257019. Here, waves propagate as indicated by arrows in a piezoelectric film 201. Here, in the piezoelectric film 201, a first main surface 201a and a second main surface 201b face each other, and a thickness direction connecting the first main surface 201a and the second main surface 201b to each other is the Z direction. The X direction is a direction in which electrode fingers of an IDT electrode are disposed side by side. As illustrated in FIG. 15A, the lamb waves propagate in the X direction in the manner illustrated in FIG. 15A. Since the waves are plate waves, the waves propagate in the X direction although the piezoelectric film 201 vibrates as a whole. Therefore, reflectors are disposed on two sides to obtain resonance characteristics. Therefore, propagation loss of the waves occurs, and the Q-value decreases when downsizing is performed, in other words, when the number of the electrode fingers is reduced.

In contrast, as illustrated in FIG. 15B, vibration displacement in the acoustic wave device 1 is in the thickness shear direction, and thus, waves propagate substantially in a direction connecting the first main surface 2a and the second main surface 2b of the piezoelectric layer 2 to each other, that is, in the Z direction and resonates. That is, the X direction component of the waves is significantly smaller than the Z direction component of the waves. Since resonance characteristics are obtained by the propagation of the waves in this Z direction, propagation loss is unlikely to occur even when the number of the electrode fingers of reflectors is reduced. Further, even when the number of pairs of electrode pairs defined by the electrodes 3 and 4 is reduced for downsizing, the Q-value is unlikely to decrease.

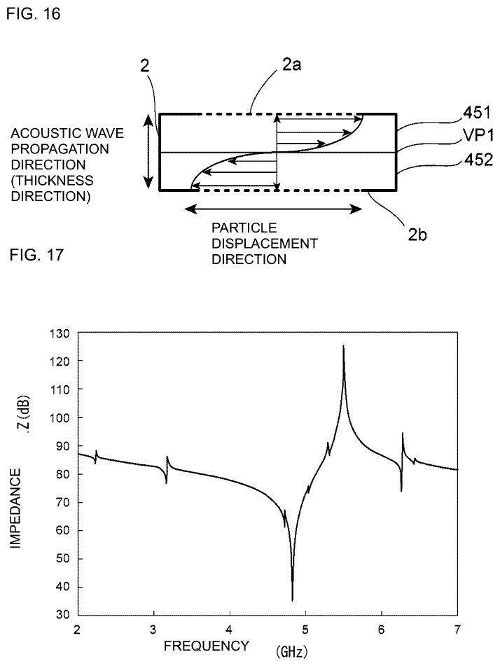

As illustrated in FIG. 16, the amplitude direction of bulk waves in the thickness shear mode for a first excitation region 451 included in the excitation regions C of the piezoelectric layer 2 and the amplitude direction of bulk waves in the thickness shear mode for a second excitation region 452 included in the excitation regions C of the piezoelectric layer 2 are opposite to each other. FIG. 16 schematically illustrates bulk waves when a voltage that causes the electrode 4 to have a higher potential than the electrode 3 is applied between the electrode 3 and the electrode 4. The first excitation region 451 is a region included in the excitation regions C and present between the first main surface 2a and an imaginary plane VP1 orthogonal to the thickness direction of the piezoelectric layer 2 and dividing the piezoelectric layer 2 in two. The second excitation region 452 is a region included in the excitation regions C and present between the second main surface 2b and the imaginary plane VP1.

Although, as described above, at least one pair of electrodes defined by the electrode 3 and the electrode 4 is disposed in the acoustic wave device 1, the pair of electrodes is not for causing waves to propagate in the X direction. Therefore, a plurality of electrode pairs defined by the electrode 3 and the electrode 4 are not required. In other words, it is sufficient that at least one pair of the electrodes is provided.

For example, the electrode 3 is an electrode that is connected to a hot potential, and the electrode 4 is an electrode that is connected to a ground potential. However, the electrode 3 may be connected to a ground potential while the electrode 4 may be connected to a hot potential. In the present preferred embodiment, each electrode of at least one pair of electrodes is, as described above, an electrode connected to a hot potential or an electrode connected to a ground potential, and no floating electrode is provided.

FIG. 17 is a graph showing resonance characteristics of the acoustic wave device illustrated in FIG. 14. Note that design parameters of an example of the acoustic wave device 1 with which the resonance characteristics are obtained are as follows.

Piezoelectric layer 2: LiNbO₃ having Euler angles (0°, 0°, 90°), thickness=400 nm

The length of a region in which the electrode 3 and the electrode 4 overlap each other when viewed in a direction orthogonal to the length directions of the electrode 3 and the electrode 4, in other words, the length of each of the excitation regions C=40 μm, the number of pairs of the electrodes defined by the electrodes 3 and 4=21 pairs, the center-to-center distance between the electrodes=3 μm, the width of each of the electrodes 3 and 4=500 nm, and d/p=0.133

Insulating layer 7: a silicon oxide film having a thickness of 1 μm

Support member 8: Si

Note that the length of each of the excitation regions C is a dimension of each of the excitation regions C in the length directions of the electrodes 3 and 4.

In the present preferred embodiment, the distance between electrodes of an electrode pair defined by the electrodes 3 and 4 is the same among all plurality of the pairs. In other words, the electrodes 3 and the electrodes 4 are disposed at an equal pitch.

FIG. 17 clearly shows that satisfactory resonance characteristics in which the fractional band is about 12.5% can be obtained despite the absence of reflectors.

Meanwhile, when the thickness of the piezoelectric layer 2 is d and the electrode center-to-center distance between the center of the electrode 3 and the center of the electrode 4 is p, as described above, in the present preferred embodiment, d/p is less than or equal to about 0.5, and is more preferably less than or equal to about 0.24, for example. This will be described with reference to FIG. 18.

Similarly to the acoustic wave device with which the resonance characteristics indicated in FIG. 17 were obtained, a plurality of acoustic wave devices were obtained where d/p was varied. FIG. 18 is a graph showing a relationship between the d/p and the fractional band as a resonator of an acoustic wave device. FIG. 18 clearly shows that, when d/p>about 0.5 is satisfied, the fractional band is less than about 5%, even when d/p is adjusted. In contrast, when d/p≤about 0.5 is satisfied, it is possible to cause the fractional band to be more than or equal to about 5% by changing d/p within the range. In other words, it is possible to provide a resonator that has a high coupling coefficient. When d/p is less than or equal to about 0.24, the fractional band can be increased to be more than or equal to about 7%, for example. In addition, by adjusting d/p within this range, it is possible to obtain a resonator having a wider fractional band and to realize a resonator having a higher coupling coefficient. Accordingly, it is discovered and confirmed found that, by setting d/p to be less than or equal to about 0.5, it is possible to form a resonator using bulk waves in the thickness shear mode and that has a high coupling coefficient.

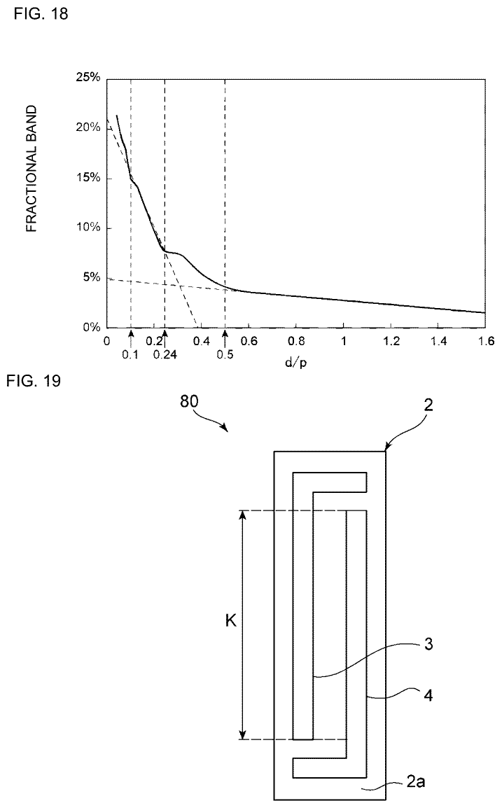

FIG. 19 is a plan view of an acoustic wave device using bulk waves in a thickness shear mode. In an acoustic wave device 80, a pair of electrodes including an electrode 3 and an electrode 4 is provided on a first main surface 2a of a piezoelectric layer 2. Note that, in FIG. 19, K is an intersection width. As described above, the number of pairs of electrodes may be one in an acoustic wave device according to a preferred embodiment of the present invention. Even in this case, it is also possible to effectively excite bulk waves in a thickness shear mode when the aforementioned d/p is less than or equal to about 0.5, for example.

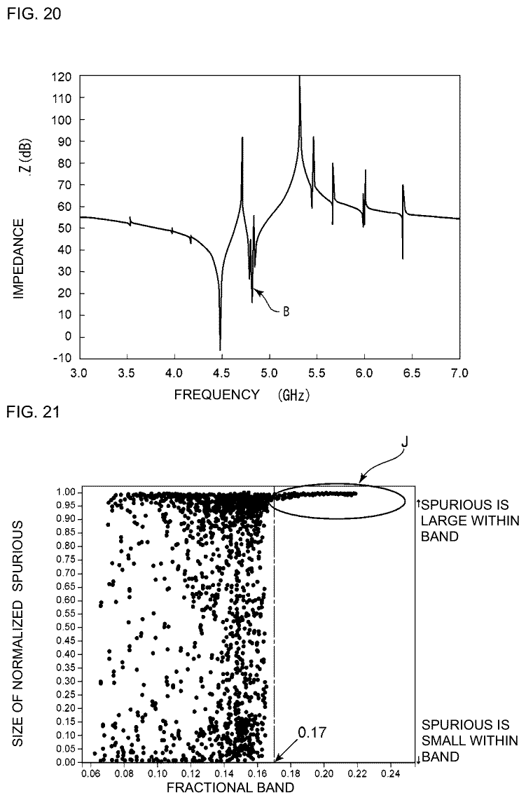

Preferably, in the acoustic wave device 1, a metallization ratio MR of, among a plurality of electrodes 3 and 4, electrodes 3 and 4 adjacent to each other with respect to an excitation region C, which is a region in which the electrodes 3 and 4 adjacent to each other overlap each other when viewed in a direction in which the electrodes 3 and 4 adjacent to each other face each other, satisfies MR about 1.75(d/p)+0.075. In such a case, it is possible to effectively cause a spurious to be small. This will be described with reference to FIG. 20 and FIG. 21. FIG. 20 is a reference graph showing one example of resonance characteristics of the acoustic wave device 1. A spurious indicated by arrow B appears between the resonant frequency and the anti-resonant frequency. Note that d/p=about 0.08 and LiNbO₃ has Euler angles (0°, 0°, 90°). In addition, the metallization ratio MR=about 0.35.

The metallization ratio MR will be described with reference to FIG. 13B. When one pair of electrodes 3 and 4 is focused upon in the electrode structure in FIG. 13B, it is assumed that only this one pair of electrodes 3 and 4 is provided. In this case, a portion surrounded by an alternate long and short dashed line is an excitation region C. This excitation region C is a region in the electrode 3 overlapping the electrode 4, a region in the electrode 4 overlapping the electrode 3, and a region in which the electrode 3 and the electrode 4 overlap each other in a region between the electrode 3 and the electrode 4, when the electrode 3 and the electrode 4 are viewed in a direction orthogonal to the length directions of the electrodes 3 and 4, that is, in the facing direction. The ratio of the areas of the electrodes 3 and 4 in the excitation region C to the area of this excitation region C is the metallization ratio MR. In other words, the metallization ratio MR is a ratio of the area of a metallization portion to the area of the excitation region C.

When a plurality of pairs of electrodes are provided, a ratio of the metallization portion included in all excitation regions to the total of the areas of the excitation regions can be considered as MR.

FIG. 21 is a graph showing a relationship between a fractional band when a large number of acoustic wave resonators are formed according to the present preferred embodiment and the phase rotation amount of an impedance of a spurious normalized by 180 degrees as the size of the spurious. Note that the fractional band was adjusted by variously changing the film thickness of the piezoelectric layer and the dimensions of the electrodes. FIG. 21 shows results when a piezoelectric layer made of Z-cut LiNbO₃ was used. However, a case where a piezoelectric layer of other cut-angles is used has the same tendency.

The spurious is about 1.0, which is large, in a region surrounded by the ellipse J in FIG. 21. FIG. 21 clearly shows that when the fractional band exceeds about 0.17, in other words, exceeds about 17%, for example, a large spurious whose spurious level is more than or equal to 1 appears in the pass band even when parameters that constitute the fractional band are changed. In other words, as with the resonance characteristics shown in FIG. 20, a large spurious indicated by the arrow B appears in the band. Therefore, the fractional band is preferably less than or equal to about 17%, for example. In this case, it is possible to cause the spurious to be small by adjusting the film thickness of the piezoelectric layer 2, the dimensions of the electrodes 3 and 4, and the like.

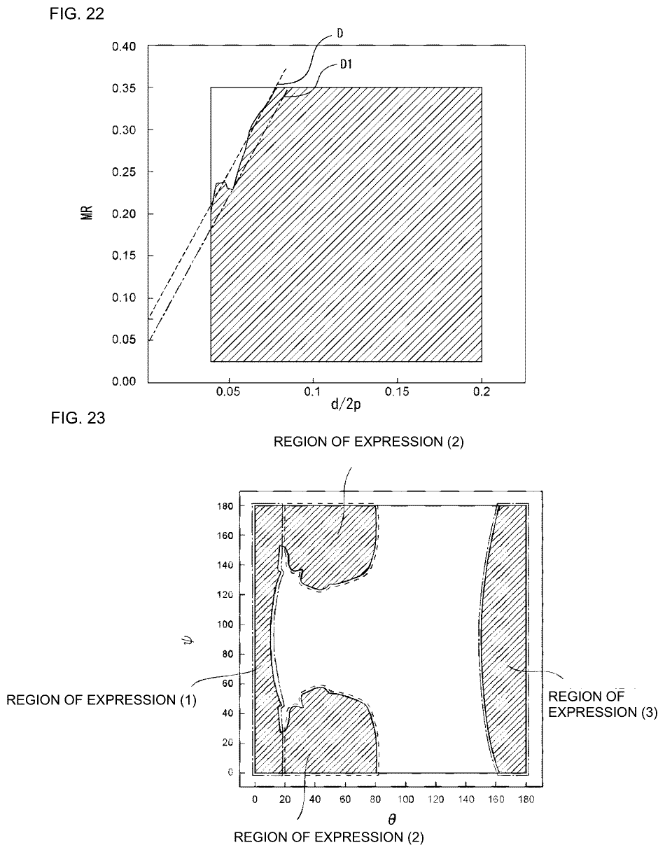

FIG. 22 is a graph showing a relationship among d/2p, the metallization ratio MR, and the fractional band. Various acoustic wave devices in which d/2p and MR differed in the above-described acoustic wave device were formed, and the fractional band was measured. In FIG. 22, the hatched portion on the right side of the dashed line D is a region in which the fractional band is less than or equal to about 17%, for example. The boundary between the hatched region and a non-hatched region is expressed by MR=about 3.5(d/2p)+0.075, for example. In other words, MR=about 1.75(d/p)+0.075, for example. Thus, preferably, MR about 1.75(d/p)+0.075, for example. In such a case, the fractional band is likely to be less than or equal to about 17%, for example. A region on the right side of MR=about 3.5(d/2p)+0.05 indicated by the alternate long and shorted dashed line D1 in FIG. 22 is more preferable. In other words, when MR≤about 1.75(d/p)+0.05 is satisfied, it is possible to reliably cause the fractional band to be less than or equal to about 17%, for example.

FIG. 23 is a graph showing a map of the fractional band with respect to the Euler angles (0°, θ, ψ) of LiNbO₃ when d/p is set as close as possible to zero. The hatched portion in FIG. 23 is a region in which a fractional band of at least more than or equal to about 5% is obtained, for example. When the range of the region is approximated, the range is expressed by Expression (1), Expression (2), and Expression (3) below.

(0°±10°,0° to 20°,optional ψ) (1)

(0°±10°,20° to 80°,0° to 60°(1−(θ−50)₂/900)^{1/2}) or (0°±10°,20° to 80°,[180°−60°(1−(θ−50)²/900)^{1/2}] to 180°) (2)

(0°±10°,[180°−30°(1−(ψ−90)²/8100)^{1/2}] to 180°,optional ψ) (3)

Accordingly, in the Euler angle range expressed by Expression (1), Expression (2), or Expression (3) above, the fractional band can be sufficiently widened, which is preferable. This is also true when the piezoelectric layer 2 is a lithium tantalate layer.

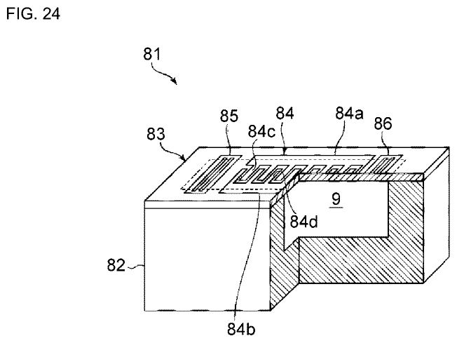

FIG. 24 is a partial cutaway perspective view for describing an acoustic wave device using lamb waves.

An acoustic wave device 81 includes a support substrate 82. A recessed portion having an open upper side is provided in the support substrate 82. A piezoelectric layer 83 is laminated to the support substrate 82. Therefore, a cavity portion 9 is formed. An IDT electrode 84 is provided on the piezoelectric layer 83 above the cavity portion 9. Reflectors 85 and 86 are provided on a corresponding one of two sides of the IDT electrode 84 in an acoustic-wave propagation direction. In FIG. 24, an outer peripheral edge of the cavity portion 9 is shown by a broken line. Here, the IDT electrode 84 includes a first busbar 84a, a second busbar 84b, a plurality of first electrode fingers 84c, and a plurality of second electrode fingers 84d. The plurality of first electrode fingers 84c are connected to the first busbar 84a. The plurality of second electrode fingers 84d are connected to the second busbar 84b. The plurality of first electrode fingers 84c and the plurality of second electrode fingers 84d interdigitate with each other.

In the acoustic wave device 81, lamb waves, which are plate waves, are excited by applying an alternating-current electric field to the IDT electrode 84 above the aforementioned cavity portion 9. Since the reflectors 85 and 86 are provided on the corresponding one of the two sides of the IDT electrode 84, it is possible to obtain resonance characteristics by the aforementioned lamb waves.

Accordingly, the acoustic wave device of the present invention may be one that uses plate waves. In this case, it is sufficient for the IDT electrode 84, the reflector 85, and the reflector 86, which are shown in FIG. 24, to be provided on the piezoelectric layer in the first preferred embodiment to the fifth preferred embodiment and each modification above.

In the acoustic wave devices, which use bulk waves in the thickness shear mode, of the first preferred embodiment to the fifth preferred embodiment and each modification, as mentioned above, d/p is preferably less than or equal to about 0.5 and, more preferably, less than or equal to about 0.24, for example. This makes it possible to obtain more satisfactory resonance characteristics. Further, in the acoustic wave devices, which use bulk waves in the thickness shear mode, of the first preferred embodiment to the fifth preferred embodiment and each modification, as mentioned above, it is preferable that MR about 1.75(d/p)+0.075 be satisfied. In this case, it is possible to more reliably reduce or prevent a spurious.

The piezoelectric layer in the acoustic wave devices, which use bulk waves in the thickness shear mode, of the first preferred embodiment to the fifth preferred embodiment and each modification is preferably made of lithium niobate or lithium tantalate. The Euler angles (ϕ, θ, ψ) of lithium niobate or lithium tantalate of which the piezoelectric layer is made is preferably in the range of Expression (1), Expression (2), or Expression (3) above. In this case, it is possible to sufficiently widen the fractional band.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a support including a support substrate;
a piezoelectric layer on the support;
a plurality of electrode fingers on the piezoelectric layer; and
two wiring electrodes to which the plurality of electrode fingers are connected at one end; wherein
the two wiring electrodes each include two busbars, the plurality of electrode fingers are connected at the one end to the two busbars, and an interdigital terminal (IDT) electrode is defined by the two busbars and the plurality of electrode fingers;
a cavity that opens on a side of the piezoelectric layer is provided in the support;
a region where adjacent ones of the electrode fingers overlap each other when viewed in a direction orthogonal to a direction in which the plurality of electrode fingers extend is an intersection region of the IDT electrode, and the cavity includes the intersection region in plan view;
a first through hole and a second through hole that directly or indirectly reach the cavity are provided in the piezoelectric layer, and the first through hole and the second through hole face each other with the intersection region being interposed therebetween; and
in plan view, a total area of the first through hole and a total area of the second through hole differ.

2. The acoustic wave device according to claim 1, wherein
the first through hole and the second through hole are each one in number; and
in plan view, an area of the first through hole and an area of the second through hole differ.

3. The acoustic wave device according to claim 2, wherein
in plan view, the area of the first through hole is larger than the area of the second through hole; and
a distance between the first through hole and the intersection region is shorter than a distance between the second through hole and the intersection region.

4. The acoustic wave device according to claim 1, wherein the piezoelectric layer includes a first region and a second region that face each other with the intersection region being interposed therebetween, and, in plan view, at least a portion of the first region and at least a portion of the second region overlap the cavity;
the first through hole is in the first region, and the second through hole is in the second region; and
the first through hole and the second through differ in number.

5. The acoustic wave device according to claim 4, wherein
a plurality of the first through holes are provided in the first region, and at least one of the second through hole is provided in the second region;
in plan view, a total area of the plurality of first through holes is larger than a total area of the at least one second through hole; and
of distances between the plurality of first through holes and the intersection region, all of the distances are shorter than a shortest distance of distances between the at least one second through hole and the intersection region.

6. The acoustic wave device according to claim 1, wherein two end portions of the intersection region in the direction orthogonal to the direction in which the plurality of electrode fingers extend are positioned on a straight line connecting the first through hole and the second through hole.

7. The acoustic wave device according to claim 1, wherein two end portions of the intersection region in the direction in which the plurality of electrode fingers extend are positioned on a straight line connecting the first through hole and the second through hole.

8. The acoustic wave device according to claim 7, wherein, in plan view, the first through hole overlaps one of the two wiring electrodes, and a through hole integrated with the first through hole is provided in the wiring electrode.

9. The acoustic wave device according to claim 8, wherein, in plan view, the first through hole overlaps one of the busbars, and the through hole integrated with the first through hole is provided in the busbar.

10. The acoustic wave device according to claim 1, wherein the first through hole and the second through hole directly reach the cavity.

11. The acoustic wave device according to claim 1, wherein
in plan view, the first through hole is provided at a position that does not overlap the cavity; and
a path that connects the first through hole and the cavity to each other is provided in the support.

12. The acoustic wave device according to claim 11, wherein
in plan view, the first through hole overlaps one of the two wiring electrodes, and a through hole integrated with the first through hole is provided in the wiring electrode; and
in plan view, the path overlaps one of the two wiring electrodes.

13. The acoustic wave device according to claim 1, wherein the acoustic wave device is structured to generate a plate wave.

14. The acoustic wave device according to claim 1, wherein the acoustic wave device is structured to generate a bulk wave in a thickness shear mode.

15. The acoustic wave device according to claim 1, wherein a ratio d/p is less than or equal to about 0.5, where d is a film thickness of the piezoelectric layer and p is a center-to-center distance between the adjacent ones of the electrode fingers.

16. The acoustic wave device according to claim 15, wherein the ratio d/p is less than or equal to about 0.24.

17. The acoustic wave device according to claim 15, wherein MR≤about 1.75(d/p)+0.075 is satisfied, where MR is a metallization ratio of the plurality of electrode fingers with respect to the intersection region.

18. The acoustic wave device according to claim 14, wherein the piezoelectric layer is made of lithium niobate or lithium tantalate; and
Euler angles (ϕ, θ, ψ) of the lithium niobate or the lithium tantalate of which the piezoelectric layer is made are in a range of Expression (1), Expression (2), or Expression (3):
(0°±10°,0° to 20°,optional ψ) (1);
(0°±10°,20° to 80°,0° to 60°(1−(θ−50)²/900)^{1/2}) or (0°±10°,20° to 80°,[180°−60°(1−(θ−50)²/900)^{1/2}] to 180°) (2); and
(0°±10°,[180°−30°(1−(ψ−90)²/8100)^{1/2}] to 180°,optional ψ) (3).

19. The acoustic wave device according to claim 1, wherein the piezoelectric layer is made of lithium niobate or lithium tantalate.

20. The acoustic wave device according to claim 1, wherein
the support includes an insulating layer between the support substrate and the piezoelectric layer; and
the cavity is in the insulating layer.

21. The acoustic wave device according to claim 1, wherein the cavity is in the support substrate.
